(19) United States
(12) Patent Application Publication
(10) Pub. No.: US 2009/0101886 A1
(43) Pub. Date: Apr. 23, 2009

(54) SEMICONDUCTOR LIGHT-EMITTING DEVICE AND METHOD OF FABRICATING THE SAME

(75) Inventor: Hsuan-Tang CHANG, Cyonglin Township (TW)

Correspondence Address: Muncy, Geissler, Olds & Lowe, PLLC, P.O. BOX 1364, FAIRFAX, VA, 22038-1364, US

(73) Assignee: HUGA OPTOTECH INC.

(21) Appl. No.: 12/128,402

(22) Filed: May 28, 2008

(30) Foreign Application Priority Data
Oct. 19, 2007 (TW) 096139089

(51) Int. Cl. H01L 33/00; H01L 21/02

(52) U.S. Cl. 257/13; 257/96; 438/47; 257/E33.049; 257/E33.05; 257/E21.002

(57) ABSTRACT

The invention discloses a semiconductor light-emitting device. The semiconductor light-emitting device includes a substrate, a first semiconductor material layer, a light-emitting layer, a second semiconductor material layer, a first transparent insulating layer, a metal layer and at least one electrode. The first semiconductor material layer, the light-emitting layer, and the second semiconductor material layer are formed in sequence on the substrate. An opening is formed on the upper surface of the second semiconductor material layer and extends to the interior of the first semiconductor material layer. The first transparent insulating layer overlays the sidewalls of the opening and substantially overlays the upper surface of the second semiconductor material layer such that a region of the upper surface is exposed. The metal layer fills the opening, overlays the exposed region, and partially overlays the first transparent insulating layer. The at least one electrode is formed on the metal layer.

### BACKGROUND OF THE INVENTION

1. Field of the Invention

The present invention relates to a semiconductor light-emitting device and, more particularly, to a semiconductor light-emitting device with a larger light-emitting area.

2. Description of the Prior Art

Nowadays, semiconductor light-emitting devices, such as Light Emitting Diodes (LEDs), have been used in a wide variety of applications, e.g., key systems, back light modules of mobile phone monitors, illuminating systems of vehicles, decorative lamps, and remote controls.

Please refer to FIG. 1. FIG. 1 is a schematic diagram illustrating an LED 1 in the prior art. As shown in FIG. 1, the LED 1 includes a substrate 10, an N-type GaN layer 12, a P-type GaN layer 16, a light-emitting layer 14, and two electrodes 18. For the operation of the LED 1, the N-type GaN layer 12 and the P-type GaN layer 16 must be electrically conducted with each other in which a first electrode 18 is formed on the P-type GaN layer 16, and a second electrode 18 is formed on the N-type GaN layer 12.

Before the second electrode 18 is formed, an etching process should be performed to partially etch the N-type GaN layer 12, the light-emitting layer 14, and the P-type GaN layer 16. Only after that, can the second electrode 18 be formed on the exposed portion of the N-type GaN layer 12. However, as shown in FIG. 1, since the light-emitting layer 14 is partially etched, the light-emitting area of the LED 1 is greatly reduced to lessen the light-emitting efficiency of the LED 1. Furthermore, the etching process leads to a high manufacturing cost of the LED 1.

Accordingly, the main scope of the invention is to provide a semiconductor light-emitting device with a larger light-emitting area to solve the above problems.

### SUMMARY OF THE INVENTION

One scope of the invention is to provide a semiconductor light-emitting device and a fabricating method thereof.

According to an embodiment of the invention, the semiconductor light-emitting device includes a substrate, a first semiconductor material layer, a light-emitting layer, a second semiconductor material layer, a first transparent insulating layer, a metal layer and at least one electrode.

The first semiconductor material layer is formed on the substrate. The light-emitting layer is formed on the first semiconductor material layer. The second semiconductor material layer is formed on the light-emitting layer and has an upper surface. An opening is formed on the upper surface of the second semiconductor material layer and extends to the interior of the first semiconductor material layer. The first transparent insulating layer overlays the side walls of the opening and substantially overlays the upper surface of the second semiconductor material layer such that a region of the upper surface is exposed. The metal layer fills the opening, overlays the exposed region and partially overlays the first transparent insulating layer. The at least one electrode is formed on the metal layer.

According to another embodiment of the invention, it is related to a method of fabricating a semiconductor light-emitting device.

First, a substrate is prepared. Then, a first semiconductor material layer is formed on the substrate. Next, a light-emitting layer is formed on the first semiconductor material layer. Subsequently, a second semiconductor material layer with an upper surface is formed on the light-emitting layer. Next, an opening is formed on the upper surface of the second semiconductor material layer, which extends to the interior of the first semiconductor material layer. Next, a first transparent insulating layer is formed to overlay the side walls of the opening and substantially overlays the upper surface of the second semiconductor material layer such that a region of the upper surface is exposed. Subsequently, a metal layer is formed to fill the opening, overlays the exposed region and partially overlays the first transparent insulating layer. Eventually, at least one electrode is formed on the metal layer.

Compared to the prior art, the semiconductor light-emitting device according to the invention has a largely increased light-emitting area, and the current diffusion inside the semiconductor light-emitting device is better. Thereby, the light-emitting efficiency of the semiconductor light-emitting device is enhanced. Moreover, the semiconductor light-emitting device according to the invention has the merits of an easier manufacturing process and lower cost.

The advantage and spirit of the invention may be understood by the following recitations together with the appended drawings.

### BRIEF DESCRIPTION OF THE APPENDED DRAWINGS

FIG. 1 is a schematic diagram illustrating a semiconductor light-emitting device in the prior art.

FIG. 2A is a sectional view illustrating a semiconductor light-emitting device according to an embodiment of the invention.

FIG. 2B is a sectional view illustrating a semiconductor light-emitting device according to another embodiment of the invention.

FIG. 3 is a top view illustrating a semiconductor light-emitting device according to the invention.

FIGS. 4A through 4M are sectional views illustrating a method for fabricating a semiconductor light-emitting device according to another embodiment of the invention.

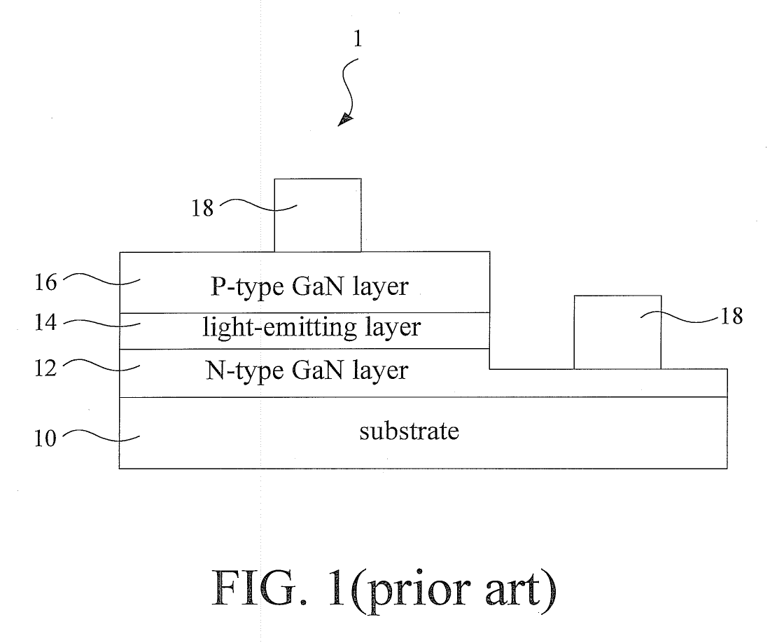

### DETAILED DESCRIPTION OF THE INVENTION

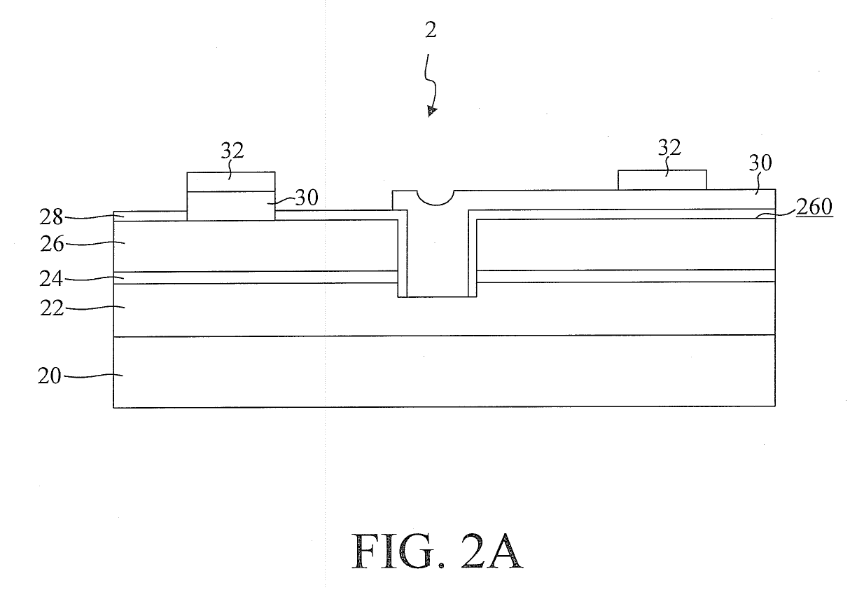

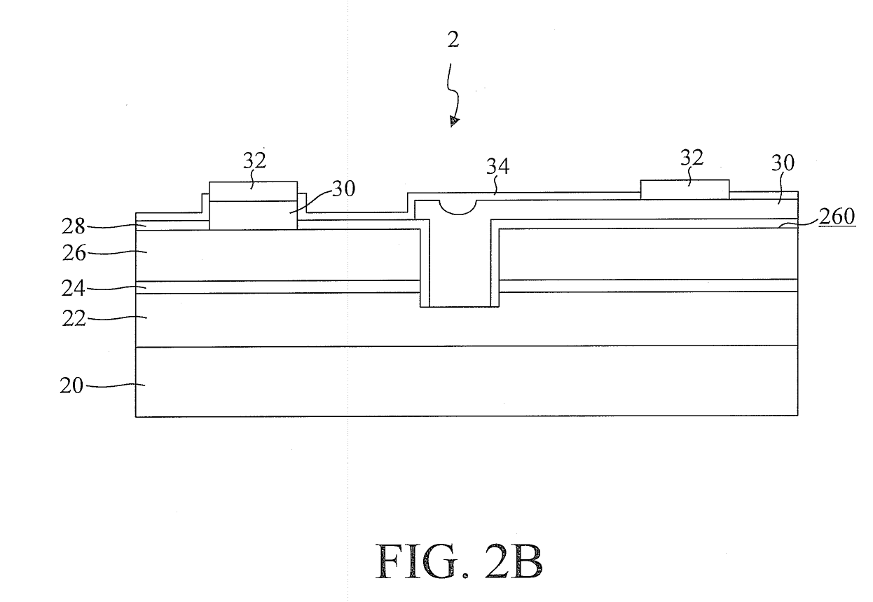

Please refer to FIG. 2A. FIG. 2A is a sectional view illustrating a semiconductor light-emitting device 2 according to an embodiment of the invention. In the embodiment, an LED is employed for the exemplification of the semiconductor light-emitting device 2, but not limited therein.

As shown in FIG. 2A, the semiconductor light-emitting device 2 includes a substrate 20, a first semiconductor material layer 22, a light-emitting layer 24, a second semiconductor material layer 26, a first transparent insulating layer 28, a metal layer 30 and at least one electrode 32.

In practical applications, the substrate 20 can be SiO₂, Si, Ge, GaN, GaAs, GaP, AlN, sapphire, spinnel, Al₂O₃, SiC, ZnO, MgO, LiAlO₂, LiGaO₂, or MgAl₂O₄.

The first semiconductor material layer 22 is formed on the substrate 20. The light-emitting layer 24 is formed on the first semiconductor material layer 22. In one embodiment, the light-emitting layer 24 can be a PN-junction, a double hetero-junction or a multiple quantum well.

The second semiconductor material layer 26 is formed on the light-emitting layer 24 and has an upper surface 260. In one embodiment, each of the first semiconductor material layer 22, the light-emitting layer 24 and the second semiconductor material layer 26 can be formed of a III-V group compound or a II-VI group compound.

In addition, an III group chemical element in the III-V group compound can be Al, Ga or In. A V group chemical element in the III-V group compound can be N, P, As or Sb. An II group chemical element in the II-VI group compound can be Be, Mg, Ca or Sr. A VI group chemical element in the II-VI group compound can be O, S, Se or Te.

The first semiconductor material layer 22 can be an N-type GaN layer, and the second semiconductor material layer 26 can be a P-type GaN layer. Alternatively, the first semiconductor material layer 22 can be a P-type GaN layer, and the second semiconductor material layer 26 can be an N-type GaN layer.

As shown in FIG. 2A, an opening is formed on the upper surface 260 of the second semiconductor material layer 26, which extends to the interior of the first semiconductor material layer 22. The first transparent insulating layer 28 overlays the side walls of the opening and substantially overlays the upper surface 260 of the second semiconductor material layer 26 such that a region of the upper surface 260 is exposed. The metal layer 30 fills the opening, overlays the exposed region and partially overlays the first transparent insulating layer 28. The at least one electrode 32 is formed on the metal layer 30.

In one embodiment, the metal layer 30 can be formed of materials such as Au, Ag, Al, Sn, or an alloy of at least two such materials. The metal layer 30 is electrically conducted with the first semiconductor material layer 22 and the second semiconductor material layer 26, respectively. The first transparent insulating layer 28 is for isolating the first semiconductor material layer 22 and the second semiconductor material layer 26.

In practical applications, to improve the ohmic contact, an ohmic contact layer can be formed between the metal layer 30 and the first semiconductor material layer 22, or between the metal layer 30 and the second semiconductor material layer 26 (not shown in FIG. 2A).

Please refer to FIG. 2B. In one embodiment, the semiconductor light-emitting device 2 further includes a second transparent insulating layer 34 formed on the first transparent insulating layer 28 and the metal layer 30.

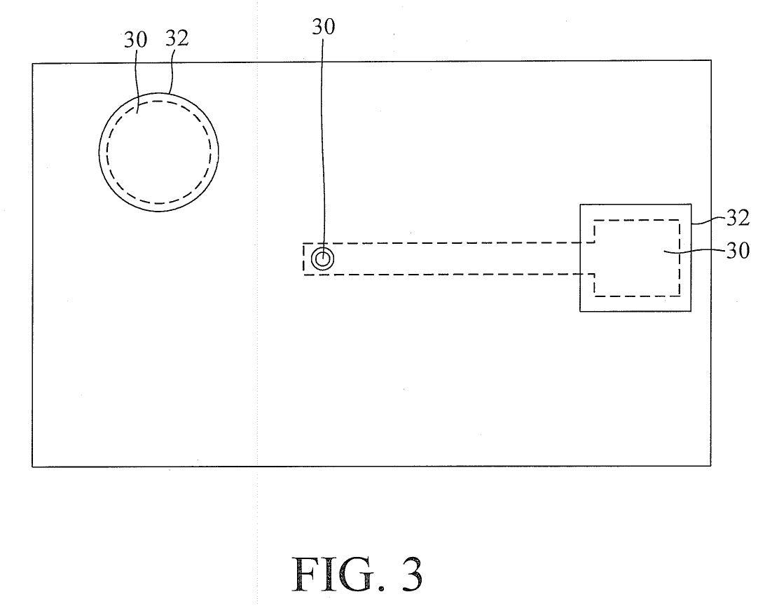

Please refer to FIG. 3. FIG. 3 is a top view illustrating a semiconductor light-emitting device 2 according to the invention. In particular, because the opening and the exposed area of the upper surface 260 of the second semiconductor material layer 26 can be formed selectively on the upper surface 260, the at least one electrode 32 can be formed optionally on the metal layer 30 after the metal layer 30 is formed. In practice, locations of the electrodes 32 will affect the diffusion of a current inside the semiconductor light-emitting device 2, which determines the light-emitting efficiency of the semiconductor light-emitting device 2. Therefore, according to the invention, the light-emitting efficiency of the semiconductor light-emitting device 2 can be enhanced by determining the location of the at least one electrode 32.

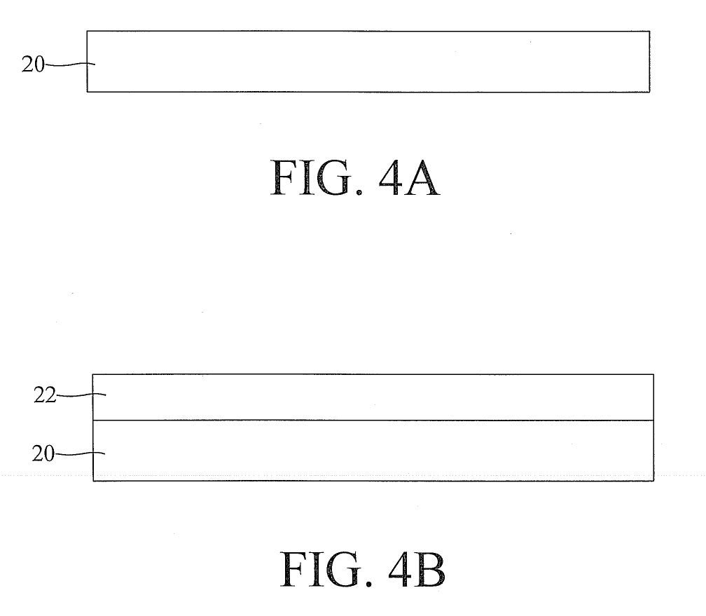

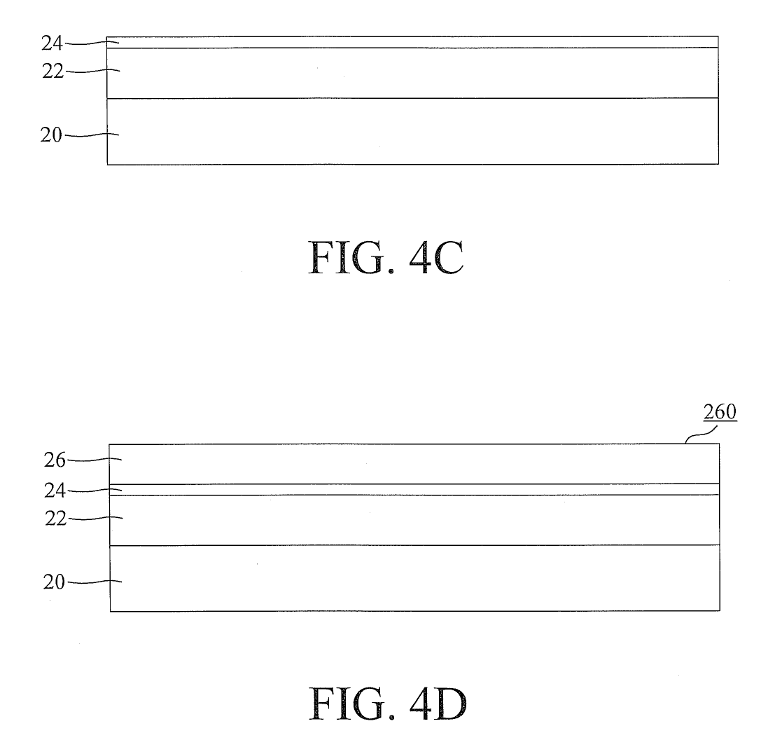

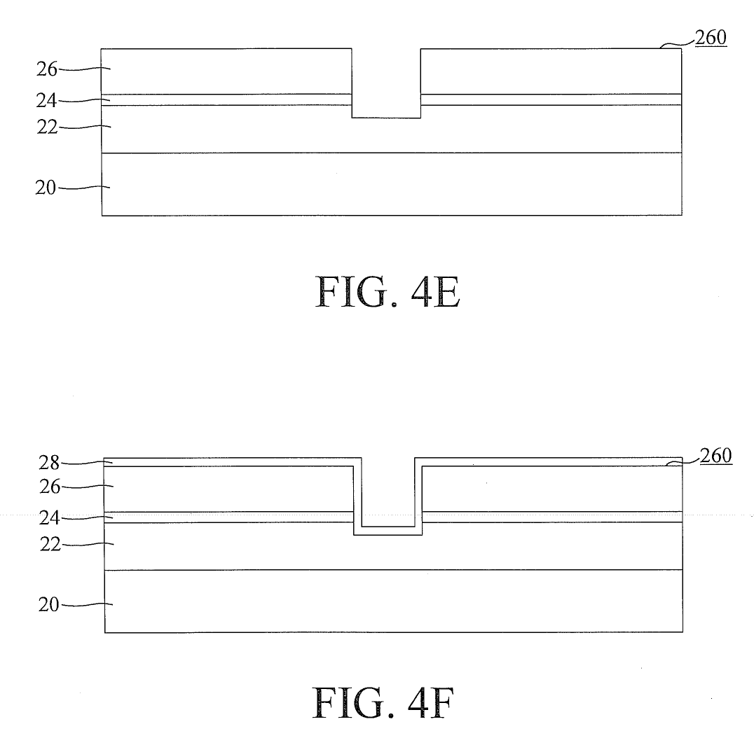

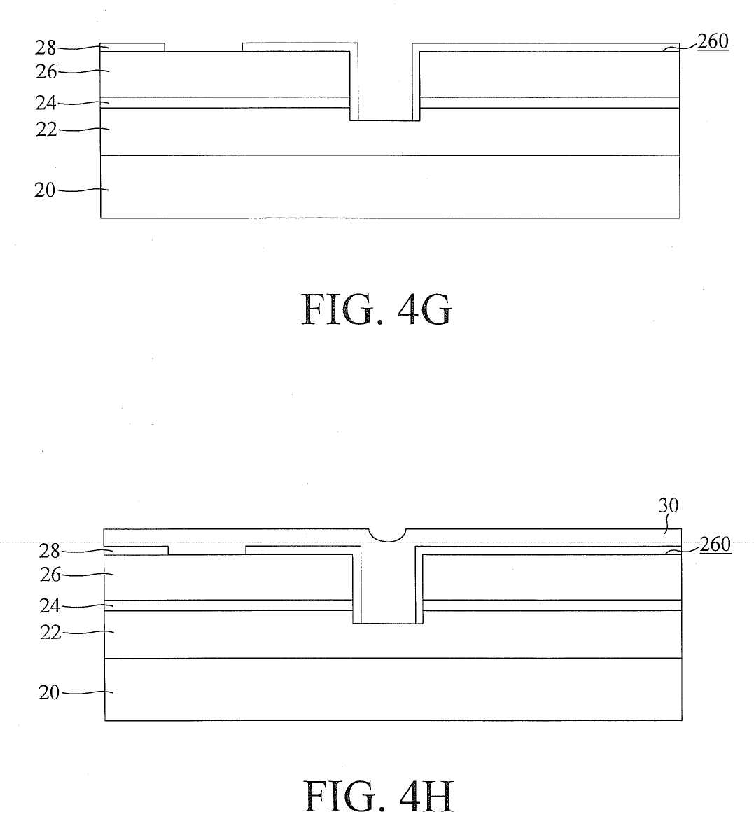

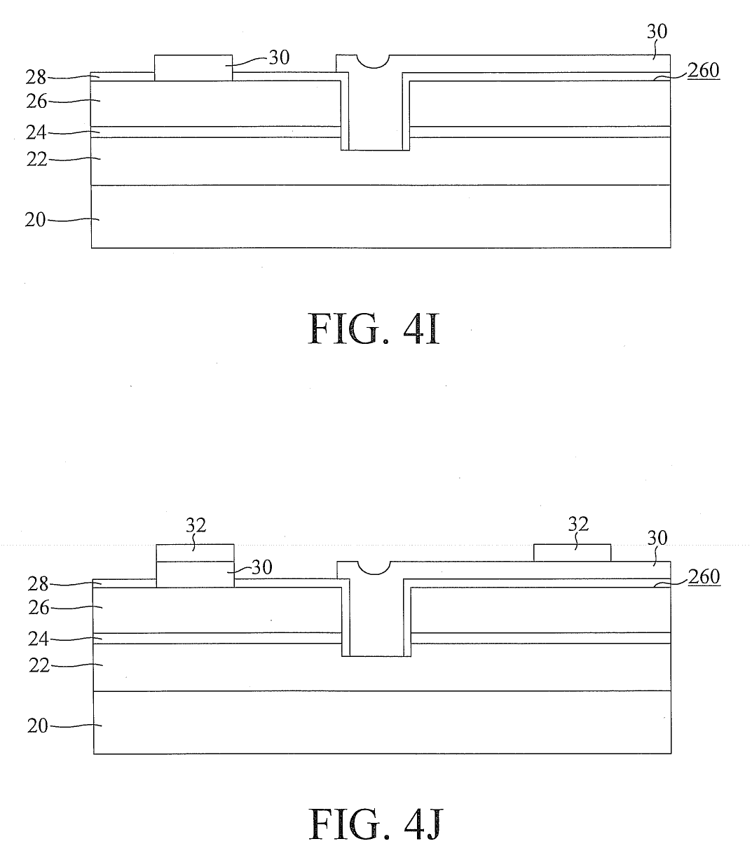

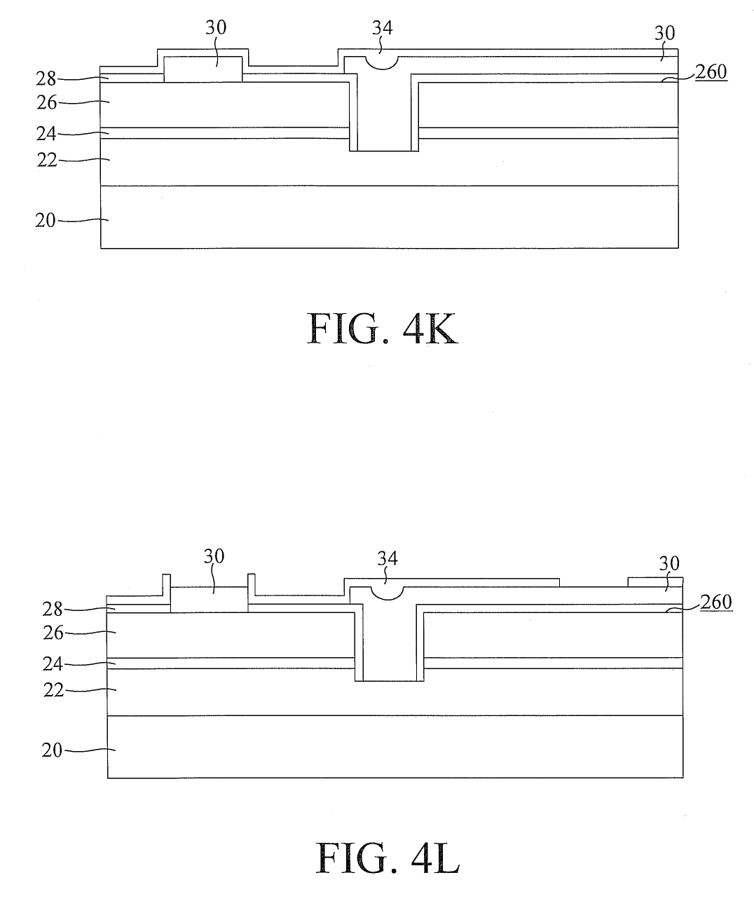

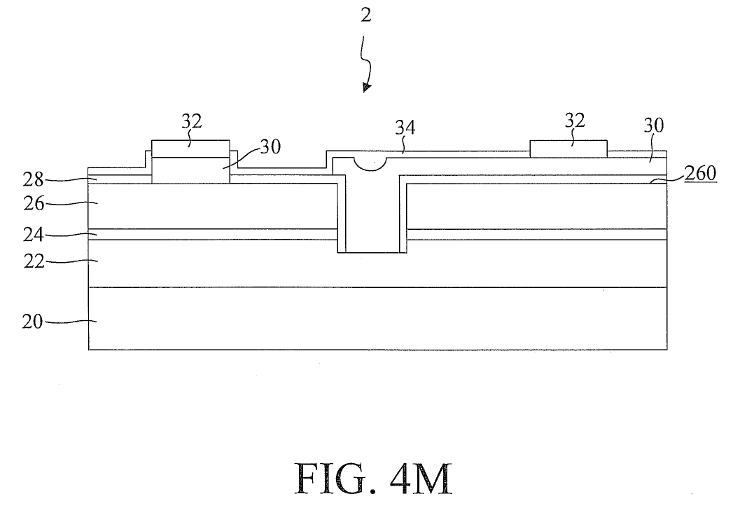

Please refer to FIG. 2A and FIGS. 4A through 4M. FIGS. 4A through 4M are sectional views illustrating a method for fabricating a semiconductor light-emitting device 2 according to another embodiment of the invention.

First, as shown in FIG. 4A, a substrate 20 is prepared.

Then, as shown in FIG. 4B, a first semiconductor material layer 22 is formed on the substrate 20.

Next, as shown in FIG. 4C, a light-emitting layer 24 is formed on the first semiconductor material layer 22.

Then, as shown in FIG. 4D, a second semiconductor material layer 26 is formed on the light-emitting layer 24. The second semiconductor material layer 26 has an upper surface 260.

Subsequently, as shown in FIG. 4E, an opening is formed on the upper surface 260 of the second semiconductor material layer 26 and extends to the interior of the first semiconductor material layer 22.

Next, as shown in FIG. 4F, a first transparent insulating layer 28 is formed on the semiconductor structure shown in FIG. 4E.

Subsequently, as shown in FIG. 4G, through an etching process, the first transparent insulating layer 28 overlays only the side walls of the opening and substantially overlays the upper surface 260 of the second semiconductor material layer 26 such that a region of the upper surface 260 is exposed.

Subsequently, as shown in FIG. 4H, a metal layer 30 is formed to overlay the semiconductor structure shown in FIG. 4G.

Then, as shown in FIG. 41, through another etching process, the metal layer 30 can fill the opening, overlay the exposed region of the upper surface 260 of the second semiconductor material layer 26 and partially overlay the first transparent insulating layer 28.

Eventually, as shown in FIG. 4J, at least one electrode 32 is formed on the metal layer 30.

Please refer to FIGS. 4K through 4M. In one embodiment, a second transparent insulating layer 34 can be selectively formed before the at least one electrode 32 is formed.

First, as shown in FIG. 4K, the second transparent insulating layer 34 is formed to overlay the first insulating layer and the metal layer 30.

Subsequently, as shown in FIG. 4L, the second transparent insulating layer 34 is selectively etched such that the metal layer 30 is partially exposed.

Eventually, as shown in FIG. 4M, the at least one electrode 32 is formed on the metal layer 30.

Compared to the prior art, the semiconductor light-emitting device according to the invention has a largely increased light-emitting area, and the current diffusion inside the semiconductor light-emitting device is better. Thereby, the light-emitting efficiency of the semiconductor light-emitting device is enhanced. Moreover, the semiconductor light-emitting device according to the invention has the merits of an easier manufacturing process and lower cost.

With the example and explanations above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

What is claimed is:

1. A semiconductor light-emitting device, comprising:
a substrate;
a first semiconductor material layer formed on the substrate;
a light-emitting layer formed on the first semiconductor material layer;
a second semiconductor material layer formed on the light-emitting layer and having an upper surface, an opening being formed on the upper surface of the second semiconductor material layer and extending to the interior of the first semiconductor material layer;
a first transparent insulating layer overlaying the side walls of the opening and substantially overlaying the upper surface of the second semiconductor material layer such that a region of the upper surface is exposed;
a metal layer filling the opening, overlaying the exposed region and partially overlaying the first transparent insulating layer; and
at least one electrode formed on the metal layer.

2. The semiconductor light-emitting device of claim 1, wherein the metal layer is formed of a material selected from the group consisting of Au, Ag, Al, Sn, and an alloy thereof.

3. The semiconductor light-emitting device of claim 1, wherein each of the first semiconductor material layer, the light-emitting layer and the second semiconductor material layer is formed of a material which is a III-V group compound or a II-VI group compound.

4. The semiconductor light-emitting device of claim 3, wherein a III group chemical element in the III-V group compound is one selected from the group consisting of Al, Ga and In, a V group chemical element in the III-V group compound is one selected from the group consisting of N, P, As and Sb.

5. The semiconductor light-emitting device of claim 3, wherein a II group chemical element in the II-VI group compound is one selected from the group consisting of Be, Mg, Ca and Sr, a VI group chemical element in the II-VI group compound is one selected from the group consisting of O, S, Se and Te.

6. The semiconductor light-emitting device of claim 1, wherein the light-emitting layer is one selected from the group consisting of a PN-junction, a double hetero-junction and a multiple quantum well.

7. The semiconductor light-emitting device of claim 1, wherein the substrate is formed of a material selected from the group consisting of SiO₂, Si, Ge, GaN, GaAs, GaP, AlN, sapphire, spinnel, SiC, Al₂O₃, ZnO, MgO, LiGaO₂, LiAlO₂, and MgAl₂O₄.

8. The semiconductor light-emitting device of claim 1, further comprising a second transparent insulating layer formed on the first transparent insulating layer and the metal layer.

9. A method of fabricating a semiconductor light-emitting device, comprising the steps of:
preparing a substrate;
forming a first semiconductor material layer on the substrate;
forming a light-emitting layer on the first semiconductor material layer;
forming a second semiconductor material layer on the light-emitting layer, the second semiconductor material layer with an upper surface;
forming an opening which is on the upper surface of the second semiconductor material layer and extends to the interior of the first semiconductor material layer;
forming a first transparent insulating layer to overlay the side walls of the opening and substantially overlay the upper surface of the second semiconductor material layer such that a region of the upper surface is exposed;
forming a metal layer to fill the opening, overlay the exposed region and partially overlay the first transparent insulating layer; and
forming at least one electrode on the metal layer.

10. The method of claim 9, wherein the metal layer is formed of a material selected from the group consisting of Au, Ag, Al, Sn, and an alloy thereof.

11. The method of claim 9, wherein each of the first semiconductor material layer, the light-emitting layer and the second semiconductor material layer is formed of a material which is a III-V group compound or a II-VI group compound.

12. The method of claim 11, wherein a III group chemical element in the III-V group compound is one selected from the group consisting of Al, Ga and In, a V group chemical element in the III-V group compound is one selected from the group consisting of N, P, As and Sb.

13. The method of claim 11, wherein a II group chemical element in the II-VI group compound is one selected from the group consisting of Be, Mg, Ca and Sr, a VI group chemical element in the II-VI group compound is one selected from the group consisting of O, S, Se and Te.

14. The method of claim 9, wherein the light-emitting layer is one selected from the group consisting of a PN-junction, a double hetero-junction and a multiple quantum well.

15. The method of claim 9, wherein the substrate is formed of a material selected from the group consisting of SiO₂, Si, Ge, GaN, GaAs, GaP, AlN, sapphire, spinner, SiC, Al₂O₃, ZnO, MgO, LiGaO₂, LiAlO₂, and MgAl₂O₄.

16. The method of claim 9, wherein before forming the at least one electrode, the method further comprising the step of:
forming a second transparent insulating layer selectively on the first transparent insulating layer or the metal layer.
